(19) United States
(12) Patent Application Publication
(10) Pub. No.: US 2013/0098757 A1
(43) Pub. Date: Apr. 25, 2013

(54) SPUTTERING DEPOSITION APPARATUS AND ADHESION PREVENTING MEMBER

(71) Applicant: ULVAC, INC., Chigasaki-shi (JP)

(72) Inventors: Tetsuhiro OHNO, Chigasaki-shi, Kanagawa (JP); Shigemitsu SATO, Chigasaki-shi, Kanagawa (JP); Tatsunori ISOBE, Sammu-shi, Chiba (JP); Tomokazu SUDA, Sammu-shi, Chiba (JP)

(73) Assignee: ULVAC, INC., Chigasaki-shi (JP)

(21) Appl. No.: 13/716,421

(22) Filed: Dec. 17, 2012

Related U.S. Application Data
(63) Continuation of application No. PCT/JP2011/063583, filed on Jun. 14, 2011.

(30) Foreign Application Priority Data
Jun. 17, 2010 (JP) 2010-138498

(51) Int. Cl. C23C 14/35

(52) U.S. Cl. CPC C23C 14/352
USPC 204/298.11

(57) ABSTRACT

An adhesion-preventing member from which a thin film of an adhered material is not peeled off during a film deposition process and a sputter deposition apparatus having the adhesion-preventing member. Adhesion-preventing members 25₁ to 25₄ and 35 are made of Al₂O₃; and an arithmetically average roughness of that adhering surface to which the sputtered particles are to be attached is between at least 4 μm and at most 10 μm to make the adhered materials difficult to be peeled off. The sputter deposition apparatus includes the adhesion-preventing members 25₁ to 25₄ and 35, arranged at positions such as surrounding outer peripheries of sputtering surfaces 23₁ to 23₄ of targets 21₁ to 21₄, or surrounding an outer periphery of a film-forming face of a substrate 31.

This application is a continuation of International Application No. PCT/JP2011/063583, filed on Jun. 14, 2011, which claims priority to Japan Patent Application No. 2010-138498, filed on Jun. 17, 2010. The contents of the prior applications are herein incorporated by reference in their entireties.

### BACKGROUND

The present invention generally relates to a sputter deposition apparatus and an adhesion-preventing member.

SiO₂ thin films are used for protection films for channel layers in thin film transistors (TFT) and barrier films for blue glass plates. Recently, as a method for the formation of a SiO₂ thin film on a surface of an area-increased substrate, reactive sputtering is generally performed for sputtering, while an Si target is being subjected to a chemical reaction in an O₂ gas ambience.

FIG. 11 shows the internal configuration view of a conventional sputter deposition apparatus 110. The sputter deposition apparatus 110 has a vacuum chamber 111 and more than one sputter units 120₁ to 120₄. The sputter units 120₁ to 120₄ have the same structure, and the following explanation uses the sputter unit associated with reference numeral 120₁ as a representative example; and the sputter unit includes a target 121₁, a backing plate 122₁ and a magnet device 126₁. The target 121₁ consists of Si; and it is formed into a flat planar shape, which is smaller than the surface of the backing plate 122₁. The entire outer periphery of the target 121₁ is positioned inside the outer periphery of the surface of the backing plate 122₁; and the target is stacked upon and affixed to the surface of backing plate 122₁ in a manner that the peripheral edge of the surface of the backing plate 122₁ is exposed from the outer periphery of the target 121₁. The target 121₁ and the backing plate 122₁ having the target 121₁ affixed to the surface thereof are hereinafter called together as a target unit.

The magnet device 126₁ is arranged on a rear surface side of the backing plate 122₁. The magnet device 126₁ includes a center magnet 127b₁, disposed linearly on a magnet fixing plate 127c₁, and an outer peripheral magnet 127a₁ on a magnet fixing plate 127c₁ that is parallel to the backing plate 122₁, and the outer peripheral magnet 127a₁ which surrounds the center magnet 127b₁ in a ring shape at a predetermined distance from the peripheral edge of the center magnet 127b₁. The outer peripheral magnet 127a₁ and the center magnet 127b₁ are respectively disposed in a manner such that their magnet poles of opposite polarities from each other facing the rear surface of the target 121₁.

A moving device 129 is arranged on a rear side of the magnet device 126₁, and the magnet device 126₁ is fixed to the moving device 129. The moving device 129 is configured to move the magnet device 126₁ in a direction parallel to the rear surface of the target 121₁.

When explaining the overall structure of the sputter deposition apparatus 110, the target units of the sputter units 120₁ to 120₄ are arranged in a line spaced apart from each other inside the vacuum chamber 111, and the surfaces of the targets 121₁ to 121₄ of the target units are arranged in order on the same plane. Each of the backing plates 122₁ to 122₄ is attached to a wall face of the vacuum chamber 111 via an insulator 114, and electrically insulated with the vacuum chamber 111.

Metallic adhesion-preventing members 125₁ to 125₄ are stood up outside the outer peripheries of the respective the backing plates 122₁ to 122₄, while being spaced from the outer peripheries of the respective backing plates 122₁ to 122₄. The adhesion-preventing members 125₁ to 125₄ are electrically connected to the vacuum chamber 111. Tip portion of the respective adhesion-preventing members 125₄ to 125₄ are bent at a right angle toward the outer peripheries of the targets 121₁ to 121₄ in the sputter units 120₁ to 120₄ and surround the surfaces of the targets 121₁ to 121₄ in ring shapes such that the tip portions cover the peripheral portions of the backing plates 122₁ to 122₄ in the respective sputter units 120₁ to 120₄. The portions of the surfaces of the respective targets 121₁ to 121₄, which are exposed from the inner peripheries of the adhesion-preventing members 125₄ to 125₄, are referred to as sputtering surfaces.

When a method for the formation of a SiO₂ thin film on a surface of a substrate 131 is explained by using the conventional sputter deposition apparatus 110, a vacuum evacuation device 112 is connected to an exhaust opening of the vacuum chamber 111, and the interior of the vacuum chamber 111 is preliminarily evacuated to vacuum. The substrate 131 is mounted on a substrate holder 132, which is transferred into the vacuum chamber 111 and stopped at a position spaced from and opposed to the sputtering surfaces of the respective targets 121₁ to 121₄.

When a gas introduction system 113 is connected to an introduction opening of the vacuum chamber 111 and a mixed gas of an Ar gas as a sputtering gas and an O₂ gas as a reactive gas is introduced into the vacuum chamber 111, the O₂ gas forms an oxide SiO₂ through a reaction with the surfaces of the respective targets 121₁ to 121₄.

When an electric power supply 137 is electrically connected to the respective backing plates 122₁ to 122₄ and AC voltages having opposite polarities from each other are applied to two adjacent targets, while one of the two adjacent targets is placed at a positive potential, the other is placed at a negative potential. Thus, an electric discharge is generated between the adjacent targets, and Ar gas among the targets 121₁ to 121₄ and the substrate 131 is plasmatized.

Alternatively, it is acceptable that the electric power supply 137 is electrically connected to each of the backing plates 122₁ to 122₄ and the substrate holder 132; AC voltages having opposite polarities from each other are applied to each of the targets 121₁ to 121₄ and the substrate 131, the electric discharge is generated between the targets 121₁ to 121₄ and the substrate 131; and Ar gas between each of the targets 121₁ to 121₄ and the substrate 131 is plasmatized. This method can also be carried out in a case of a single target.

Ar ions in the plasma are trapped in magnetic fields formed at surfaces on the targets 121₁ to 121₄ opposite to the backing plates 122₁ to 122₄ by the magnet devices 126₁ to 126₄. When each of the targets 121₁ to 121₄ is put in a negative potential, the Ar ions are crashed onto the sputtering surfaces of the targets 121₁ to 121₄, thereby flicking particles of SiO₂.

With respect to the magnetic field formed on each of the targets 121₁ to 121₄, since the above-mentioned magnet devices 126₁ to 126₄ become structurally non-uniform, the Ar ions concentrate at portions having a relatively high magnetic density, so that the targets 121₁ to 121₄ are shaved faster as compared to portions around them. In order to prevent the formation of those portions (erosion) of the targets 121₁ to 121₄ which are locally shaved in this way, sputtering is carried out, while the magnet devices 126₁ to 126₄ are being moved in areas inside the outer peripheries of the sputtering surfaces of the targets 121₁ to 121₄.

A part of SiO₂ flicked out from the sputtering surfaces of the targets 121₁ to 121₄ adheres onto the surface of the substrate 131 to form a thin film of SiO₂ on the surface of the substrate 131.

At such time, a part of SiO₂ flicked out from the targets 121₁ to 121₄ adheres onto the surfaces of the adhesion-preventing members 125₁ to 125₄. There was a problem that the thin films of the adhesion material adhered onto the surfaces of the adhesion-preventing members 125₁ to 125₄ peel off from the surface of the adhesion-preventing members 125₁ to 125₄ during the sputtering, and scatter inside the vacuum chamber 111, so that abnormal electric discharge (arcing) is induced and the thin film formed on surface of the substrate 131 is contaminated.

Not only in the case where the insulative SiO₂ thin film is formed on the surface of the substrate 131, as explained above, but also in the case where an electroconductive thin film of a metal is formed, there was a problem in that thin films of adhesion material adhered onto the surfaces of the adhesion-preventing members 125₁ to 125₄ were peeled off from the adhesion-preventing members 125₁ to 125₄ during the film formation and the thin film formed on the surface of the substrate 131 was contaminated.

### PRIOR ART LITERATURES

### Patent Document

Patent Document 1: Japanese Unexamined Patent Application Publication No. 2008-025031

### SUMMARY OF THE INVENTION

The present invention was created to solve the disadvantages of the above-mentioned prior art; and objects thereof is to provide an adhesion-preventing member from which a thin film of an adhesion material is not peeled off during a film deposition process, and to provide a sputter deposition apparatus having such adhesion-preventing member.

The present invention is to solve the above-mentioned problems, and is a sputter deposition apparatus for forming a film on a film deposition surface of a substrate arranged at a position facing a sputtering surface of a target, said sputter deposition apparatus comprising: a vacuum chamber; a vacuum evacuation device evacuating the inside of the vacuum chamber; a gas introduction system introducing a gas into the vacuum chamber; a target having a sputtering surface exposed inside the vacuum chamber; an electric power supply for applying a voltage to the target; and an adhesion-preventing member arranged at a position in which sputtered particles sputtered from the sputtering surface of the target are to be attached, wherein the adhesion-preventing member comprises Al₂O₃, and an arithmetically average roughness of that adhering face of a surface of the adhesion-preventing member to which the sputtered particles are attached is at least 4 μm to at most 10 μm.

The present invention is the sputter deposition apparatus, wherein the adhesion-preventing member comprises a target-side adhesion-preventing member arranged for the target such that the target-side adhesion-preventing member surrounds the sputtering surface of the target.

The present invention is the sputter deposition apparatus, wherein the target comprises a plurality of targets, the targets are arranged in a line spaced apart from each other inside the vacuum chamber, the sputtering surfaces of the targets are arranged to be positioned on the same plane, and the electric power supply applies an alternative voltage between two adjacent targets, and wherein a gap between an outer periphery of the sputtering surface of one of the two adjacent targets and an outer periphery of the sputtering surface of the other target is covered with the target-side adhesion-preventing member.

The present invention is the sputter deposition apparatus, wherein the target comprises a plurality of targets, the targets are arranged in a line spaced apart from each other inside the vacuum chamber, sputtering surfaces of the targets are arranged to be positioned on the same plane, and the electric power supply applies either a DC voltage or an AC voltage between each of the targets and a substrate arranged at a position facing the sputtering surface of the target, and wherein a gap between an outer periphery of the sputtering surface of one of the two adjacent targets and the sputtering surface of the other target is covered with the target-side adhesion-preventing member.

The present invention is the above-described sputter deposition apparatus, wherein the adhesion-preventing member comprises a target-side adhesion-preventing member arranged for the substrate such that the target-side adhesion-preventing member surrounds a periphery of the film-forming surface of the substrate.

The present invention is the above-described sputter deposition apparatus, wherein the target comprises SiO₂.

The present invention is the above-described sputter deposition apparatus, wherein the target comprises Si, and the gas introduction system is O₂ gas source for discharging the O₂ gas.

The present invention is the adhesion-preventing member which is arranged at that position in a film deposition apparatus to which film deposition particles are to be attached, the film deposition apparatus comprising: a vacuum chamber; a vacuum evacuating device evacuating the inside of the vacuum chamber; and a unit for discharging film deposition particles from a film deposition materials arranged inside the vacuum chamber, wherein the adhesion-preventing member comprises Al₂O₃, and an arithmetically average roughness of that adhering face of the surface of the adhesion-preventing member to which the sputtered particles are to be attached is set at between at least 4 μm and at most 10 μm.

The present invention is the adhesion-preventing member which is arranged at that position in an film deposition apparatus to which film deposition particles are attached, wherein the film deposition apparatus comprising: a vacuum chamber; a vacuum evacuating device evacuating the inside of the vacuum chamber; a gas introduction system introducing a gas into the vacuum chamber; and a reacting unit producing the film deposition particles from a chemical reaction of the gas introduced into the vacuum chamber, wherein the adhesion-preventing member comprises Al₂O₃, and an arithmetically average roughness of that adhering surface on the surface of the adhesion-preventing member to which the sputtered particles are to be adhered is set at between at least 4 μm and at most 10 μm.

Note that the arithmetic average roughness (Ra) is prescribed in JIS B0601:2001.

Since a thin film on an adhesion material is not peeled off from the adhesion-preventing member, contamination of the thin film formed on the substrate by an adhesion materials on the thin film can be prevented; and thus, the quality of the thin film formed on the substrate can be improved.

Even if the adhesion material is insulative, because the adhesion-preventing member is also insulative, neither insulation breakdown nor arcing occurs on the thin film of the adhesion material. Therefore, the adhesion-preventing member can be prevented from being damaged by the arcing; and it is possible to prevent the contamination of the thin film formed on the substrate caused by impurities originating from the arcing.

### BRIEF EXPLANATION OF THE DRAWINGS

FIG. 1 is an internal structure view of a sputter deposition apparatus of the present invention.

FIG. 2 is a sectional view along line A-A of FIG. 1 of the sputter deposition apparatus of the present invention.

FIG. 3 is a sectional view along line B-B of FIG. 1 of the sputter deposition apparatus of the present invention.

FIG. 4 is an internal structure view of a vacuum evaporation apparatus.

FIG. 5 is an internal structure view of a PE-CVD apparatus.

FIG. 6 is an internal structure view of a Cat-CVD apparatus.

FIG. 7 is a photograph of an adhering surface of a first test adhesion-preventing member after the testing step.

FIG. 8 is a photograph of an adhering surface of a second test adhesion-preventing member after the testing step.

FIG. 9 is a photograph of an adhering surface of a third test adhesion-preventing member after the testing step.

FIG. 10 is a photograph of an adhering surface of a fourth test adhesion-preventing member after the testing step.

FIG. 11 is the internal structure view of the conventional sputter deposition apparatus.

### DETAILED DESCRIPTION OF THE INVENTION

### First Embodiment if the Sputter Deposition Apparatus of the Present Invention

The structure of a first embodiment of the sputter deposition apparatus of the present invention will now be explained.

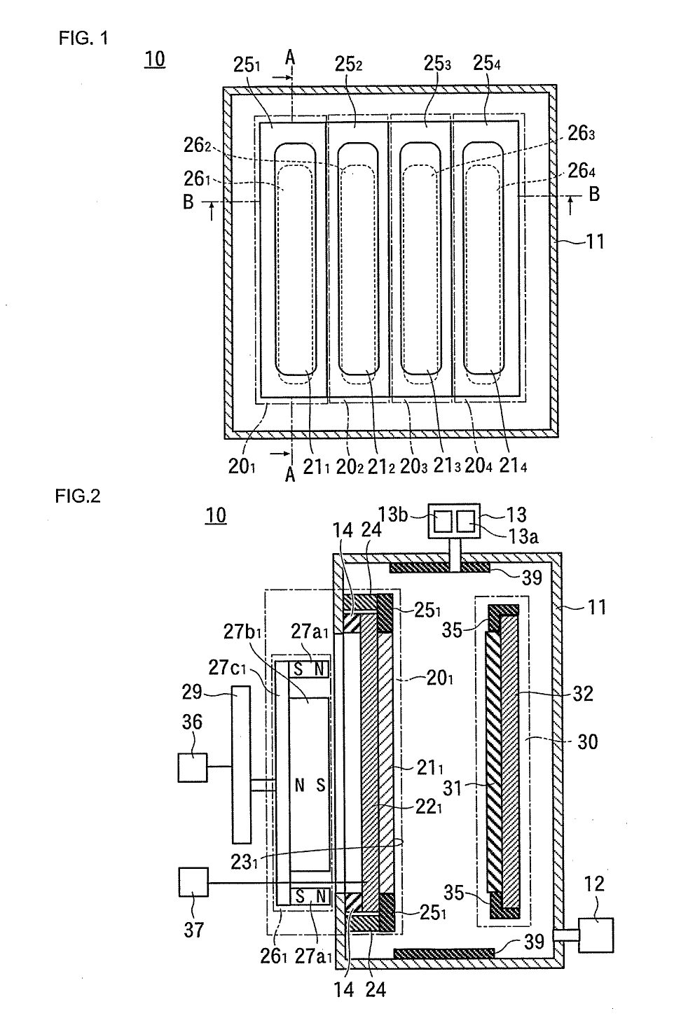

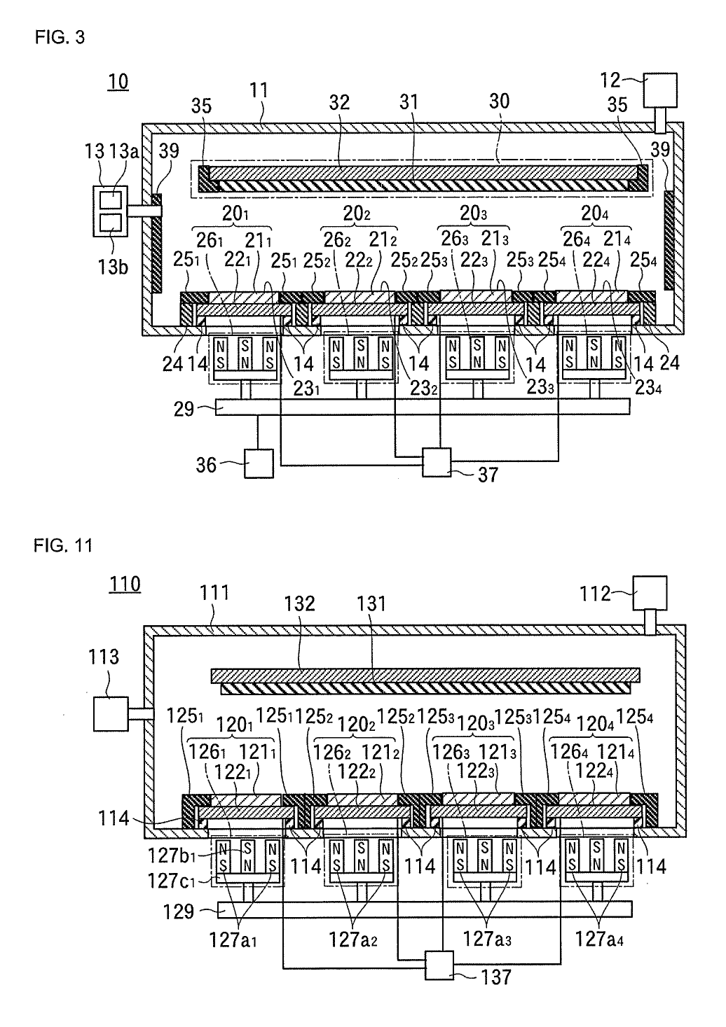

FIG. 1 is an internal structure view of a sputter deposition apparatus 10; FIG. 2 is a sectional view along an A-A line of FIG. 1; and FIG. 3 is a sectional view along a B-B line of FIG. 1.

The sputter deposition apparatus 10 includes a vacuum chamber 11, and a plurality of sputter units 20₁ to 20₄. The structure of the sputtering units 20₁ to 20₄ includes targets 21₁ to 21₄ having sputtering surfaces 23₁ to 23₄ exposed inside the vacuum chamber 11, and the targets 21₁ to 21₄ arranged on the surfaces of the backing plates 22₁ to 22₄, and magnet devices 26₁ to 26₄.

The structure of each of the sputtering units 20₁ to 20₄ is the same; and thus, the structural arrangement of the sputtering unit 20₁ will be explained as a representative example of the sputter units.

The target 21₁ is formed into a flat planar shape with a surface which is smaller than the surface of a backing plate 22₁; the entire outer periphery of the target 21₁ is positioned on the inside of the outer periphery of the backing plate 22₁; and the target 21₁ is stacked upon and affixed to the surface of the backing plate 22₁ in a manner such that the entire peripheral edge of the backing plate 22₁ is exposed from the outer periphery of the target 21₁. The target 21₁ and the backing plate 22₁ having a surface affixed to the target 21₁ is hereinafter referred to as a target unit.

A magnet device 26₁ includes an outer peripheral magnet 27a₁, a center magnet 27b₁, and a magnet fixing plate 27c₁. In this embodiment, the center magnet 27b₁ is linearly arranged on a surface of the magnet fixing plate 27c₁, and the outer peripheral magnet 27a₁ annularly surrounds the center magnet 27b₁ on the surface of the magnet fixing plate 27c₁, while being separated from the peripheral edge of the center magnet 27b₁ by a predetermined distance.

In other words, the outer peripheral magnet 27a₁ is formed in a ring shape, and the center magnet 27b₁ is arranged inside the ring of the outer peripheral magnet 27a₁. The “ring shape” as used here refers to a shape surrounding the periphery of the center magnet 27b₁, and does not necessarily mean one seamless circular ring. In other words, as long as it surrounds the periphery of the center magnet 27b₁, and the ring may have plurality of parts and have linear shape at a certain portion thereof. Moreover, a closed circular ring or a closed and deformed circular ring may be employed.

A magnet device 26₁ is arranged on a rear surface side of the backing plate 22₁. As to a magnet fixing plate 27c₁ of the magnet device 26₁, its surface on which the center magnet 27b₁ and the outer peripheral magnet 27a₁ are arranged to face the rear surface of the backing plate 22₁. Different magnetic polarities from each other are arranged respectively at a portion of the outer peripheral magnet 27a₁ facing the rear surface of the backing plate 22₁ and a portion of the center magnet 27b₁ facing the rear surface of the backing plate 22₁.

In other words, the magnet device 26₁ comprises a center magnet 27b₁ arranged in a direction in which a magnetic field is generated on the sputtering surface 23₁, and an outer peripheral magnet 27a₁ arranged so as to be in a continuous shape around the center magnet 27b₁. The center magnet 27b₁ and the outer peripheral magnet 27a₁ are arranged in such a manner that magnetic poles having different polarities from each other face the sputtering surface 23₁. That is, the magnetic polarities of the magnetic pole of that portion of the outer peripheral magnet 27a₁ which faces the rear surface of the target 21₁ and the magnetic polarities of the magnetic pole of that portion of the center magnet 27b₁ which faces the rear surface of the target 21₁ are different from each other.

A moving device 29 as an XY stage is arranged on a rear surface side of the magnet fixing plate 27c₁; and the magnet device 26₁ is fixed to the moving device 29. A control unit 36 is connected to the moving device 29; and the transfer device 29 is constructed to transfer the magnet device 26₁ in a direction parallel to the rear surface of the target 21₁ upon receipt of a control signal from the control unit 36.

When the magnet device 26₁ is moved by the moving device 29, a magnetic field formed on the target 21₁ by the magnet device 26₁ moves on the surface of the target 21₁ accompanied with the movement of the magnet device 26₁.

The overall structure of the sputter deposition apparatus 10 will now be explained. For an exhaust opening and an introduction inlet of the vacuum chamber 11, a vacuum evacuation device 12 is connected to the exhaust opening, and a gas introducing system 13 is connected to the introduction inlet. The vacuum evacuation device 12 is constructed to evacuate the inside of the vacuum chamber 11 through the exhaust opening. The gas introduction system 13 has a sputtering gas source 13a for discharging a sputtering gas and a reactive gas source 13b for discharging a reactive gas and reactable with the targets 21₁ to 21₄ in the respective sputter units 20₁ to 20₄ so that a mixed gas of the sputtering gas and the reactive gas can be introduced into the vacuum chamber 11 through the introduction inlet.

The target portions in the respective sputter units 20₁ to 20₄ are arranged in a line inside the vacuum chamber 11, while being separated from one another; and the surfaces of the targets 21₁ to 21₄ of the respective target portions are aligned to be positioned in the same plane.

The backing plates 22₁ to 22₄ of the sputter units 20₁ to 20₄ are attached to a wall surface of the vacuum chamber 11 via columnar insulating materials 14; and the backing plates 22₁ to 22₄ of the sputter units 20₁ to 20₄ are electrically insulated from the vacuum chamber 11.

An electric power supply 37 is electrically connected to the backing plates 22₁ to 22₄ in the respective sputter units 20₁ to 20₄. The electric power supply 37 is constructed to apply an AC voltage to the backing plates 22₁ to 22₄ of the sputter units 20₁ to 20₄, while shifted between two adjacent targets by a half cycle. When AC voltage having opposite polarities from each other is applied to the two adjacent targets, one of the two adjacent targets is set to a positive potential, and the other target is set to a negative potential; consequently, an electric discharge is generated between the adjacent targets. The frequency of the AC voltage is preferably 20 kHz to 70 kHz (that is, between at least 20 kHz and at most 70 kHz) because the electric discharge can be stabilized and maintained between the adjacent targets, and is, preferably, 55 kHz.

The electric power supply 37 of the present invention is not only constructed to apply the AC voltage to the backing plates 22₁ to 22₄ in the sputter units 20₁ to 20₄, but also may be constructed to apply pulse-like negative voltages thereto for more than once. In this case, after the application of the negative voltage is finished and before starting to apply the negative voltage to one of the two adjacent targets, the negative voltage is applied to the other of the two adjacent targets.

The sputter deposition apparatus 10 includes adhesion-preventing members positioned to the place where sputtered particles discharged by sputtering from sputtering surfaces 23₁ to 23₄ of the targets 21₁ to 21₄ are adhered.

The adhesion-preventing members comprise target-side adhesion-preventing members 25₁ to 25₄ positioned on the targets 21₁ to 21₄ in such manner that they surround the peripheries of the sputtering surfaces 23₁ to 23₄ of the targets 21₁ to 21₄.

In other words, the ring-shaped target-side adhesion-preventing members 25₁ to 25₄ are positioned outside of the outer peripheries of the respective targets 21₁ to 21₄. The “ring shape” as used here refers to a shape surrounding the periphery of the sputtering surfaces 23₁ to 23₄ of the targets 21₁ to 21₄, and does not necessarily mean one seamless circular ring. In other words, as long as it surrounds the periphery of the sputtering surfaces 23₁ to 23₄ of the targets 21₁ to 21₄, and the ring may have plurality of parts and have a linear shape at a certain portion thereof.

The target-side adhesion-preventing members 25₁ to 25₄ comprise Al₂O₃; and the arithmetically average roughness of those faces (hereinafter referred to as adhering surfaces or faces) of the surfaces of the target-side adhesion-preventing members 25₁ to 25₄, which are exposed to the outer sides of the outer peripheries of the sputtering surfaces 23₁ to 23₄ of the targets 21₁ to 21₄, is set to between at least 4 μm and at most 10 μm. As shown by the Examples, as discussed below, the adhering surfaces of the target-side adhesion-preventing members 25₁ to 25₄ having the arithmetically average roughness of between at least 6 μm and at most 10 μm is the most preferable.

The structural arrangements of the sputter units 20₁ to 20₄ are the same; and thus, the sputter unit 20₁ will be explained as a representative example. As shown in FIG. 2, the outer periphery of the ring of the target-side adhesion-preventing member 25₁ is larger than the outer periphery of the backing plate 22₁, and the inner periphery of the ring of the target-side adhesion-preventing member 25₁ is the same as or larger than the outer periphery of the target 21₁ here.

The target-side adhesion-preventing member 25₁ is arranged on a surface of the backing plate 22₁ to which the target 21₁ is fixed at such a relative position that the center of the ring of the target-side adhesion-preventing member 25₁ overlaps with the center of the target 21₁; and the target-side adhesion-preventing member covers that peripheral edge portion of the backing plate 22₁ which is exposed from outer periphery of the target 21₁, so that the inner periphery of the target-side adhesion-preventing member 25₁ surrounds the outer periphery of the target 21₁.

The inner periphery of the ring is preferably as small as possible should the below-mentioned plasma enter a gap between the inner periphery of the ring of the target-side adhesion-preventing member 25₁ and the outer periphery of the target 21₁.

The entire surface of the target 21₁ is exposed to inside of the ring of the target-side adhesion-preventing member 25₁, so that the entire front surface of the target 21₁ constitutes the sputtering surface to be sputtered. A reference numeral 23₁ denotes the sputtering surface.

When the sputtering surface 23₁ of the target 21₁ is sputtered as explained later, a portion of particles discharged from the sputtering surface 23₁ are adhered to the adhesion surface of the target-side adhesion-preventing member 25₁; therefore, the particles do not adhere to the surface of the backing plate 22₁.

The target-side adhesion member 25₁ in the present invention is not limited to the case in which the inner periphery of the ring of the target-side adhesion-preventing member 25₁ is the same as or larger than the outer periphery of the target 21₁, but it includes a case in which the inner periphery of the ring of the target-side adhesion-preventing member 25₁ is smaller than the outer periphery of the target 21₁. In this case, when the target-side adhesion-preventing member 25₁ is arranged on the surface of the target 21₁ as explained above, the target-side adhesion-preventing member 25₁ covers the peripheral portion of the target 21₁; and thus, the portion of the surface of the target 21₁ which is exposed from the inside of the ring of the target-side adhesion-preventing member 25₁ becomes the sputtering surface 23₁ to be sputtered.

In other words, the target-side adhesion-preventing member 25₁ is set at that edge portion of the target 21₁ where the face side of the surface of the target 21₁ which includes the sputtering surface 23₁ becomes discontinuous, and surrounds the periphery of the sputtering surface 23₁.

As far as the relationship between the one putter unit (for example, a reference numeral 20₁) among the sputtering units 20₁ to 20₄ and another sputtering unit 20₂ adjacent thereto is concerned, the gap between the outer periphery of the sputtering surface 23₁ of one target 21₁ of the two adjacent targets 21₁, 21₂ and the outer periphery of the sputtering surface 23₂ of the other target 21₂ is covered with the target-side adhesion-preventing members 25₁, 25₂.

Therefore, the sputtered particles discharged from the respective sputtering surfaces 23₁ and 23₂ do not permeat the gap between the outer periphery of the sputtering surface 23₁ of one target 21₁ and the outer periphery of the sputtering surface 23₂ of the other target 21₂.

Columnar supporting members 24 are erected outside of the outer peripheries of the backing plates 22₁ to 22₄, and the target-side adhesion-preventing members 25₁ to 25₄ are attached on the tips of the supporting members 24.

When the supporting member 24 is electroconductive, the supporting member 24 is spaced from the outer periphery of the backing plate 22₁. The electroconductive supporting member 24 is electrically connected to the vacuum chamber 11. However, the target-side adhesion-preventing member 25₁ is electrically insulative; therefore, the backing plate 22₁ is electrically insulated from the vacuum chamber 11, even though the target-side adhesion-preventing member 25₁ contacts the backing plate 22₁.

Furthermore, when the supporting member 24 is either electroconductive or electrically insulative, the target-side adhesion-preventing members 25₁ to 25₄ are electrically floating.

The sputter deposition apparatus 10 includes a substrate holding plate 32 for holding the substrate 31.

When the substrate 31 is held by the substrate holding plate 32, the substrate 31 is positioned in such a manner that it faces the surfaces of the respective targets 21₁ to 21₄ (the sputtering surfaces 23₁ to 23₄). The size of the surface of the substrate holding plate 32 is made larger compared to the size of the surface of the substrate 31, so that the entire outer periphery of the substrate 31 is positioned inside of the outer periphery of the substrate holding plate 32; and the substrate 31 is held at the surface of the substrate holding plate 32 at such a relative position, so that the entire periphery of the peripheral edge portion of the substrate holding plate 32 is exposed from the outer periphery of the substrate 31.

The surface of the substrate 31 on which a film is to be deposited is exposed inside the vacuum chamber 11.

Here, the adhesion-preventing member comprises a substrate-side adhesion-preventing member 35 which is arranged on the substrate 31 in such a manner that surrounds the periphery of the deposition surface of the substrate 31.

In other words, the ring-shaped substrate-side adhesion-preventing member 35 is arranged on the outer side of the outer periphery of the substrate 31. The “ring shape” as used here refers to a shape surrounding the periphery of the deposition surface of the substrate 31, and does not necessarily mean one seamless circular ring. In other words, as long as it surrounds the periphery of the deposition surface of the substrate 31, the ring may have a plurality of parts and have linear shape at a certain portion thereof.

The substrate-side adhesion-preventing member 35 comprises Al₂O₃, and the arithmetic average roughness of the face (hereinafter referred to as adhering surface) of the surface of the substrate-side adhesion-preventing member 35, which is exposed outside of the outer periphery of the film forming surface of the substrate 31, is set at between at least 4 μm and at most 10 μm. As explained later by way of the Examples, the arithmetic average roughness of that adhering surface of the substrate-side adhesion-preventing member 35 is the most preferable when set at between at least 6 μm and at most 10 μm.

The outer periphery of the ring of the substrate-side adhesion-preventing member 35 is larger than the outer periphery of the substrate holding plate 32, whereas the inner periphery of the substrate-side adhesion-preventing member 35 is the same or larger than the outer periphery of the film deposited face of the surface of the substrate 31 on which a film is deposited.

The substrate-side adhesion-preventing member 35 is positioned on the surface of the substrate holding plate 32 for holding the substrate 31 at such a relative position that the center of the ring of the substrate-side adhesion-preventing member 35 overlaps with that of the film forming surface of the substrate 31; and the substrate-side adhesion-preventing member covers the peripheral portion of the substrate holding plate 32 exposed from the outer periphery of the substrate 31, and surrounds the outer periphery of the film forming surface of the substrate 31 with the inner periphery of the ring of the substrate-side adhesion-preventing member 35.

As explained later, when the sputtering surfaces 23₁ to 23₄ of the respective targets 21₁ to 21₄ are sputtered, a part of the particles discharged from the respective sputtering surfaces 23₁ to 23₄ are adhered onto the surface of the substrate 31 and the adhering surface of the substrate-side adhesion-preventing member 35, respectively, but not adhered onto the surface of the substrate holding plate 32.

Hereinafter, the substrate 31, the substrate holding plate 32 for holding the substrate 31 and the substrate-side holding member 35 surrounding the outer periphery of the film forming surface of the substrate 31 are referred to as an object to be processed 30.

A method for sputter deposition of a SiO₂ thin film on the film deposition surface of the substrate 31 by using the sputter deposition apparatus 10 will be explained.

First, an explanation is made of a measuring step for determining the protruding minimum value as the minimum value and the protruding maximum value as the maximum value of a distance by which a portion of the outer peripheries of the outer peripheral magnets of the magnet device 26₁ to 26₄ in the sputter units 20₁ to 20₄ protrude from the outer peripheries of the sputtering surfaces 23₁ to 23₄ of the target 21₁ to 21₄ in the sputter units 20₁ to 20₄.

In reference to FIG. 2 and FIG. 3, the target units of the sputter units 20₁ to 20₄ are carried into the vacuum chamber 11, and placed on the insulating materials 14. Here, Si is used as the targets 21₁ to 21₄ of the sputtering units 20₁ to 20₄.

The target-side adhesion-preventing members 25₁ to 25₄ are fixed to the supporting members 24, and the sputtering surfaces 23₁ to 23₄ of the targets 21₁ to 21₄ of the sputtering portions 20₁ to 20₄ are exposed on the inside of the rings of the target-side adhesion-preventing members 25₁ to 25₄.

The inside of the vacuum chamber 11 is evacuated by the vacuum evacuating device 12. Afterward, the vacuum ambience inside the vacuum chamber 11 is maintained by continuous vacuum evacuation.

While the object to be processed 30 is not carried into the vacuum chamber 11, the gas introduction system 13 introduces the mixed gas of the sputtering gas and the reactive gas. Here, Ar gas is used as the sputtering gas, and O₂ gas is used as the reactive gas, whereas the mixed gas is introduced into the vacuum chamber 11 at such a flow rate which makes a so-called Oxide Mode in which the O₂ gas introduced from the reactive gas source 13b(O₂ gas source) into the vacuum chamber 11 reacts with the surfaces of the targets 21₁ to 21₄ of the sputter units 20₁ to 20₄, and an electrically insulative oxide SiO₂ is formed on the surfaces on the targets 21₁ to 21₄. Here, Ar gas is introduced at a flow rate of 50 sccm and the O₂ gas is introduced at a flow rate of 150 sccm.

The vacuum chamber 11 is set at a ground potential. When AC voltages of 20 kHz to 70 kHz are applied from the electric power supply 37 to the backing plates 22₁ to 22₄ of the sputter units 20₁ to 20₄, an electric discharge is generated between the adjacent targets 21₁ to 21₄, and Ar gas above the targets 21₁ to 21₄ in the sputter units 20₁ to 20₄ is ionized and then plasmatized.

Ar ions in the plasma are trapped in a magnetic fields formed by the magnet devices 26₁ to 26₄ of the sputter units 20₁ to 20₄. When a negative voltage is applied to the backing plates 22₁ to 22₄ of the sputter units 20₁ to 20₄ from the electric power supply 37, the Ar ions collide against the sputtering surfaces 23₁ to 23₄ of the targets 21₁ to 21₄ on the backing plates 22₁ to 22₄ to which the negative voltage is applied, and SiO₂ particles formed on the sputtering surfaces 23₁ to 23₄ are stricken off. The state of the sputter units 20₁ to 20₄ during the sputtering is the same, so the following explanation uses the sputter unit associated with reference numeral 20₁ as a representative example.

While moving the magnet device 26₁ by the moving device 29, the magnetic field formed above the surface of the target 21₁ by the magnet device 26₁ moves above the surface of the target 21₁ together with the plasma trapped in the magnetic field, and the surface of the target 21₁ is continuously sputtered along a movement trajectory of the plasma.

When the magnet device 26₁ is moved in a movement area in which the entire outer periphery of the outer peripheral magnet 27a₁ is located inside the outer periphery of the sputtering surface 23₁, a central portion of the sputtering surface 23₁ is sputtered and shaved in a concaved form. The area of the sputtering surface 23₁ which is shaved by sputtering is referred as an erosion area. The sputtering surface 23₁ is shaved to the point where the location of the outer peripheral of the erosion area is visually recognized.

Next, the composition and the pressure of the gas evacuated under vacuum from the inside of the vacuum chamber 11 are being monitored as the movement area of the magnet device 26₁ is gradually widened, and the amount by which a portion of the outer periphery of the outer peripheral magnet 27a₁ protruded to the outside of the outer periphery of the sputtering surface 23₁ is gradually increased.

As the amount of the portion of the outer periphery of the outer peripheral magnet 27a₁ which protrudes to the outside of the outer periphery of the sputtering surface 23₁ increases, the horizontal component of the magnetic field on the target-side adhesion-preventing member 25₁ increases; and when the target-side adhesion-preventing member 25₁ is shaved by sputtering, the gas composition inside the vacuum chamber 11 changes during the evacuation. When the sputtering of the adhesion-preventing member 25₁ has been confirmed by the change in the gas composition during the evacuation based on the change in the gas composition in the vacuum chamber 11, the amount of protrusion of the outer periphery of the outer peripheral magnet 27a₁ from the outer periphery of the sputtering surface 23₁ is measured.

In a producing step to be explained later, if the target-side adhesion-preventing member 25₁ is shaved by sputtering, the particles from the target-side adhesion-preventing member 25₁ adhere to the surface of the substrate 31, and a film formed on the surface of the substrate 31 becomes contaminated with impurities. Accordingly, the amount of protrusion measured here is stored in the control unit 36 as the maximum protruding value.

In the case where the degree of the hardness of the target-side adhesion-preventing member 25₁ is so high that it cannot be sputtered (i.e., when a portion of the outer periphery of the outer peripheral magnet 27a₁ protrudes to the inside of the sputtering surface 23₂ of the adjacent target 21₂, and the sputtering surface 23₂ of the adjacent target 21₂ is shaved), the pressure inside the vacuum chamber 11 changes. When the sputtering of the sputtering surface 23₂ of the adjacent target 21₂ has been confirmed from the change in pressure inside the vacuum chamber 11, the amount of protrusion of the outer periphery of the outer peripheral magnet 27a₁ from the outer periphery of the sputtering surface 23₁ is measured.

In a producing step to be explained later, if the sputtering surface 23₂ of the target 21₂ in the sputter unit 20₂ is shaved by the plasma trapped in the magnetic field of the magnet device 26₁ in the adjacent sputter unit 20₁, the flatness of a thin film formed on the surface of the substrate 31 is deteriorated; therefore, the amount of protrusion measured here is stored in the control unit 36 as the maximum protruding value.

Next, in reference to FIG. 3, the application of the voltage to the backing plates 22₁ to 22₄ of the sputter units 20₁ to 20₄ is stopped, the introduction of the mixed gas from the gas introduction system 13 is stopped, and the sputtering is terminated.

The target-side adhesion-preventing member 25₁ to 25₄ of the sputter units 20₁ to 20₄ are removed from the supporting members 24; and the target portions of the sputter units 20₁ to 20₄ are carried to the outside of the vacuum chamber 11.

The size of the gap between the outer periphery of the erosion area and the outer periphery of the sputtering surface 23₁ is measured from the target 21₁ of the target portion carried to the outside of the vacuum chamber 11. It is understood that as the inside of the above described distance from the outer periphery of the outer peripheral magnet 27a₁ is shaved by sputtering, the size of the gap measured here is stored in the control unit 36 as the minimum protruding value.

Next, in reference to FIG. 3 as the producing step, fresh target portions of the sputter units 20₁ to 20₄ are carried to the inside of the vacuum chamber 11, and positioned on the insulating materials 14.

The target-side adhesion-preventing members 25₁ to 25₄ are fixed to the supporting members 24, and the sputtering surfaces 23₁ to 23₄ of the targets 21₁ to 21₄ of the sputter units 20₁ to 20₄ are exposed inside the rings of the target-side adhesion-preventing members 25₁ to 25₄.

The inside of the vacuum chamber 11 is evacuated by the vacuum evacuation device 12. Consequently, the vacuum ambience is maintained inside the vacuum chamber 11 by continuous evacuation.

The object to be processed 30 is carried into the inside of the vacuum chamber 11, and is then stopped at a position where the film deposition surface of the substrate 31 on the object to be processed 30 faces the sputtering surfaces 23₁ to 23₄ of the targets 21₁ to 21₄ of the sputter units 20₁ to 20₄.

The mixed gas of the sputtering gas and the reactive gas is introduced from the gas introduction system 13 into the vacuum chamber 11 at the same flow rates as in the above described measuring step. The surfaces of targets 21₁ to 21₄ of the sputter units 20₁ to 20₄ react with the O₂ gas introduced into the vacuum chamber 11 as the reactive gas; and thus, SiO₂ is formed.

Similar to the measuring step, the AC voltage is applied to the backing plates 22₁ to 22₄ of the sputter units 20₁ to 20₄ from the electric power supply 37; and the Ar gas between the targets 21₁ to 21₄ of the sputter units 20₁ to 20₄ and the substrate 31 is plasmatized to sputter the sputtering surfaces 23₁ to 23₄ of the targets 21₁ to 21₄ of the sputter units 20₁ to 20₄.

A portion of SiO₂ particles sputtered from the sputtering surfaces 23₁ to 23₄ of the targets 21₁ to 21₄ of the sputter units 20₁ to 20₄ adheres to the film deposition surface of the substrate 31; and thus, the thin film of SiO₂ is formed on the film deposition surface of the substrate 31.

A portion of the SiO₂ particles sputtered from the sputtering surfaces 23₁ to 23₄ of the targets 21₁ to 21₄ adheres to the adhering surfaces of the target-side adhesion-preventing members 25₁ to 25₄ and the adhering surface of the substrate-side adhesion-preventing member 35. The target-side adhesion-preventing members 25₁ to 25₄ and the substrate-side adhesion-preventing members 35 both comprise Al₂O₃, and the arithmetically average roughness of the adhering surfaces of the target-side adhesion-preventing members 25₁ to 25₄ and the arithmetically average roughness of the adhering surfaces of the substrate-side adhesion-preventing member 35 are both set at between at least 4 μm and at most 10 μm; and as explained later in the Examples below, the thin films of the attached material adhered to the adhering surfaces of the adhesion-preventing members 25₁ to 25₄ and 35 during the sputtering are not peeled off from the adhering surfaces. Thus, a problem (such as, the thin film on the adhered material peeled off from the adhering surfaces of the adhesion-preventing members 25₁ to 25₄, and 35 scatter inside the vacuum chamber 11 to induce arcing, or adhere to the surface of the substrate 31 to contaminate the thin film formed on the deposition surface of the substrate 31) does not occur.

Further, since the target-side adhesion-preventing members 25₁ to 25₄ are insulative, no insulation breakdown occurs on the adhered films of SiO₂ deposited on the adhering surfaces of the target-side adhesion-preventing members 25₁ to 25₄, and no arcing occurs above the target-side adhesion-preventing members 25₁ to 25₄. Since no arcing occurs above the target-side adhesion-preventing members 25₁ to 25₄, damage to the target-side adhesion-preventing members 25₁ to 25₄ due to the arcing can be prevented. Also, the contamination of the thin film formed on the film forming surface of the substrate 31 by impurities originating from the arcing can be prevented.

The state of the sputter units 20₁ to 20₄ during the sputtering is the same. Therefore, the following explanation uses the sputter unit associated with reference numeral 20₁ as a representative example.

Here, the control unit 36 is constructed to move the magnet device 26₁ between a position in which the entire outer periphery of the outer peripheral magnet 27a₁ is positioned inside the outer periphery of the sputtering surface 23₁ of the target 21₁; and a position in which a portion of the outer periphery of the outer peripheral magnet 27a₁ protrudes from the outer periphery of the sputtering surface 23₁.

In other words, the magnet device 26₁ is constructed to move between a position in which the entire outer periphery of the outer periphery magnet 27a₁ is included inside the inner periphery of the adhesion-preventing member 25₁ that surrounds the periphery of the sputtering surface 23₁ and a position in which a portion of the outer periphery of the outer peripheral magnet 27a₁ protrudes outside from the inner periphery of the adhesion-preventing member 25₁ that surrounds the periphery of the sputtering surface 23₁.

When a portion of the outer periphery of the outer peripheral magnet 27a₁ protrudes from the outer periphery of the sputtering surface 23₁ during the sputtering, the plasma trapped in the magnetic field of the magnet device 26₁ contacts the target-side adhesion-preventing member 25₁; however, since the target-side adhesion-preventing member 25a₁ is made of an electrically insulated material, no arcing occurs when the plasma contacts the target-side adhesion-preventing member 25₁. Therefore, when compared to the prior art, a preferable wider area of the sputtering surface 23₁ of the target 21₁ can be sputtered.

The control unit 36 of the present invention is not limited to the above construction, but the control unit may be constructed to make the magnet device 26₁ move in an area where the entire outer periphery of the outer peripheral magnet 27a₁ is included inside of the outer periphery of the sputtering surface 23₁ of the target 21₁. However, it is preferable to have a case where a portion of the outer periphery of the outer peripheral magnet 27a₁ protrudes outside the outer periphery of the sputtering surface 23₁, and a case where a wider area of the sputtering surface 23₁ can be sputtered.

Here, the control unit 36 makes a portion of the outer periphery of the outer peripheral magnet 27a₂ protrude from the outer periphery of the sputtering surface 23₁ by a distance longer than the minimum protruding value determined in the measuring step; and while the magnet device 26₁ is being moved, and when the members such as, backing plate 22₁ or the like, between the target 21₁ and the magnet device 26₁ are ignored, the magnet device 26₁ which the surface facing the rear side surface of the target 21₁ of the outer peripheral magnet 27a₁ does not pass the position that is right on back of the same portion of the sputtering surface 23₁ of the target 21₁, but the surface of the outer peripheral magnet 27a₁ facing the rear side surface of the target 21₁ is made to move to pass everywhere on the right on back of the entire sputtering surface 23₁ of the target 21₁.

Moreover, when the outer peripheral magnet 27a₁ protrudes to the outer periphery of the sputtering surface 23₁, it does not protrude from the same portion of the outer periphery, and the magnet device 26₁ is made to move so that the outer peripheral magnet 27a₁ protrudes at least once from every portion of the outer periphery of the sputtering surface 23₁.

Consequently, the entire sputtering surface 23₁ inside the outer periphery is shaved by sputtering, and SiO₂ re-adhering on the sputtering surface 23₁ is not deposited on the sputtering surface 23₁. Since insulative SiO₂ is deposited on the surface of the electroconductive target in the prior art, arcing occurs on the target due to the insulation breakdown of the deposited SiO₂; however, with respect to the present invention, SiO₂ is not deposited on the target 21₁; thus, no arcing occurs on the target 21₁.

The target 21₁ can be prevented from being damaged from the arcing because no arcing occurs on the target 21₁. Also, the thin film formed on the substrate 31 can be prevented from being contaminated by impurities.

Furthermore, the control unit 36 is constructed to make the outer periphery of the outer peripheral magnet 27a₁ protrude from the outer periphery of the sputtering surface 23₁ by a distance smaller than the maximum protrusion value determined in the measuring step. Therefore, the target-side adhesion-preventing member 25₁ can be prevented from being shaved by sputtering; and the contamination of the thin film formed on the substrate 31 by impurities can be prevented.

As to the relationship between one of the sputter units 20₁ to 20₄ (for example, the sputter unit 20₁) and another sputter unit 20₂ adjacent thereto, the control unit 36 is constructed to make the magnet device 26₁ in the one sputter unit 20₁ to move between a position where the entire outer periphery of the outer peripheral magnet 27a₁ of the magnet device 26₁ is included in a place inside the outer periphery of the sputtering surface 23₁ of the target 21₁ in the sputter unit 20₁, and to also move from a position where a portion of the outer periphery of the outer peripheral magnet 27a₁ protrudes to the outer periphery of the sputtering surface 23₁ to the outer periphery of the sputtering surface 23₂ of the target 21₂ of another sputter unit 20₂ which is adjacent to the target 21₁.

In other words, when an area between the outer periphery of the sputtering surface 23₁ of the target 21₁ in one sputter unit 20₁ and the outer periphery of the sputtering surface 23₂ of the target 21₂ in another sputter unit 20₂ adjacent to the sputter unit 20₁ is referred as an outer area, the control unit 36 is constructed to make the magnet device 26₁ in the sputter unit 20₁ move between the position where the entire outer periphery of the outer peripheral magnet 27a₁ of the magnet device 26₁ is included inside the outer periphery of the sputtering surface 23₁ of the target 21₁ in the sputter unit 20₁ and the position where the entire outer periphery of the outer peripheral magnet 27a₁ of the magnet device 26₁ protrudes into the outer area.

In other words, the magnet device 26₁ arranged on a back side of the sputtering face 23₁ of at least one target 21₁ is constructed to move between the position in which the entire outer periphery of the outer peripheral magnet 27a₁ is included inside the inner periphery of the adhesion-preventing member 25₁ surrounding the periphery of the sputtering surface 23₁ of the target 21₁ and the position where a portion of the outer periphery of the outer peripheral magnet 27a₁ protrudes between the outer side of the inner periphery of the adhesion-preventing member 25₁ of the target 21₁ and the inner periphery of the adhesion-preventing member 25₂ surrounding the periphery of the sputtering surface 23₂ of another target 21₂ adjacent to the target 21₁.

Therefore, regarding the present invention, if the size of the sputtering surface 23₁ to 23₄ of the targets 21₁ to 21₄ of the sputter units 20₁ to 20₄ are the same as in the prior art and the distance between the outer periphery of the sputtering erosion area of the sputtering surface 23₁ of the target 21₁ in one sputter unit (here, reference numeral 20₁) and the outer periphery of the erosion area of the sputtering surface 23₂ of the target 21₂ in another sputter unit 20₂ adjacent thereto is also set the same as in the prior art, the distance of the gap between the outer peripheries of the adjacent targets 21₁ to 21₄ can be made wider compared to the prior art. Therefore, the amount of the target material used can be reduced and the reduction in cost can be attained.

In reference to FIG. 2 and FIG. 3, after thin films of SiO₂ are formed in a predetermined thickness on the film forming surface of the substrate 31 by continuous sputtering of the sputtering surfaces 23₁ to 23₄ of the targets 21₁ to 21₄ for a predetermined time period, the application of the voltage to the backing plates 22₁ to 22₄ in the sputter units 20₁ to 20₄ is stopped, the introduction of the mixed gas from the gas introduction system 13 is stopped, and the sputtering is terminated.

The object to be processed 30 that have undergone the treatment is carried to the outside of the vacuum chamber 11, and sent to a succeeding step. Then, an unprocessed object to be processed 30 is carried into the inside of the vacuum chamber 11, and the above explained producing step of the sputtering film deposition is repeated.

In the above description, the case in which the sputter deposition apparatus 10 is equipped with a plurality of the sputter units has been explained, but the present invention can include a case with only one sputter unit. In this case, an electric power supply is electrically connected to a backing plate and a substrate holder, an AC voltages having opposite polarities from each other are applied to a target and a substrate, an electric discharge is generated between the target and the substrate, and it is enough to plasmatize the sputtering gas between the target and the substrate.

In the above explanation, the target of the sputter units and the substrates are in the state where they are standing and are facing towards each other. However, the present invention is not limited to such a structural arrangement as long as the sputtering surface of the target of the sputter units and the film deposition surface of the substrate are faced toward each other (that is, that they can face each other by arranging the substrate above the target of each sputter units, and they face each other by arranging the substrate below the target of each sputter unit). If the substrate is arranged under the target in each of the sputter units, particles may fall onto the substrate causing the quality of the thin film to deteriorate. Therefore, it is preferable to arrange the substrate above the target of each sputter units, or as explained above, to arrange the substrate and the target of each sputter unit to face each other in a state where they are standing.

In FIG. 1, although the flat planar shape of the magnet devices 26₁ to 26₄ is represented as an elongated shape, the flat planar shape of the magnet devices 26₁ to 26₄ of the present invention is not limited to the elongated shape.

In the above explanation, at first, the O₂ gas is reacted with the surfaces of the targets 21₁ to 21₄ of Si to form SiO₂ on the surface of the targets 21₁ to 21₄; and then, the thin film of SiO₂ is formed by sputtering the surfaces of the targets 21₁ to 21₄. However, the present invention also includes a case such that by sputtering the surfaces of Si 21₁ to 21₄ without O₂ gas being reacted with the targets 21₁ to 21₄, Si particles are discharged from the surfaces of the targets 21₁ to 21₄ and are reacted with O₂ gas to form a thin film of SiO₂.

In the above explanation, a case in which the thin film of SiO₂ is formed by sputtering the Si target while O₂ gas is introduced into the vacuum chamber 11; however, a case in which a thin film of SiO₂ is formed by sputtering a SiO₂ target is also included in the present invention.

Furthermore, the present invention can be used in a case in which a target of a metallic material (such as, Al or the like) is sputtered to form a metallic thin film.

Also, if O₂ gas is not used in the deposition of the film, the O₂ gas source 13b may be omitted from the gas introduction system 13 in the sputter deposition apparatus 10.

The adhesion-preventing member of the present invention is not limited to the target-side adhesion-preventing members 25₁ to 25₄ arranged at the positions surrounding the outer peripheries of the sputtering surfaces 23₁ to 23₄ of the targets 21₁ to 21₄ and the substrate-side adhesion-preventing member 35 arranged at the position surrounding the outer periphery of the film forming surface of the substrate 31, as long as the adhesion-preventing member is at a position where the sputtered particles discharged from the sputtering surfaces 23₁ to 23₄ of the targets 21₁ to 21₄ by sputtering are adhered. For example, the present invention may have an adhesion-preventing member arranged on an inner wall surface of the vacuum chamber 11. Reference numeral 39 denotes the adhesion-preventing member arranged on the inner wall surface of the vacuum chamber 11.

In the case where the material of the inner wall surface of the vacuum chamber 11 is Al₂O₃, the inner wall surface of the vacuum chamber 11 itself may be used, after being treated to the arithmetically average roughness of at least 4 μm to at most 10 μm without the adhesion-preventing member 39 being attached to the inner wall surface of the vacuum chamber 11. However, it is much more preferable if the adhesion-preventing member 39 is attached to the inner wall surface because the cleaning of the vacuum chamber 11 is much easier.

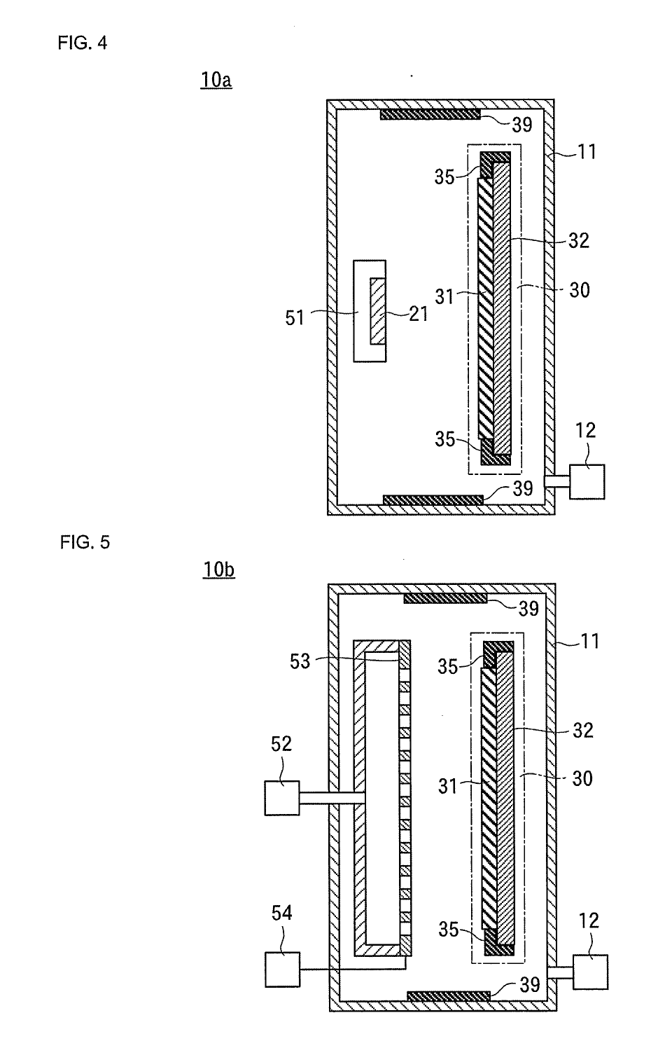

The adhesion-preventing member regarding the present invention comprises Al₂O₃; and as long as the arithmetically average roughness of that adhering surface on the face of the adhesion-preventing member to which the film deposition particles are adhered to is set at between at least 4 μm and at most 10 μm, the adhesion-preventing member is not limited to those used in the sputter deposition apparatus as explained above. Moreover, in reference to FIG. 2 and FIG. 4, the present invention includes the adhesion-preventing members 25₁, 35 and 39, which are arranged at the positions where the film deposition particles of the film deposition apparatuses 10, 10a; whereas, the film deposition apparatuses comprising a vacuum chamber 11, a vacuum evacuating device 12 evacuating the inside of the vacuum chamber 11, a discharging means for discharging the film deposition particles from the film deposition materials 21₁, 21 arranged inside the vacuum chamber 11 and constructed to deposit the film deposition material on the surface of the substrate 31, are adhered to.

Here, discharging means is: in reference to FIG. 2, in case where the film deposition apparatus 10 is a sputtering apparatus, it is the introduction system 13 for introducing gas into the vacuum chamber 11, and the electric power supply 37 that makes the introduced gas to collide against the target by accelerating the gas; and in reference to FIG. 4, in case where the film deposition apparatus 10a is a vapor deposition apparatus, it is a heating apparatus 51 for heating a film deposition materials 21.

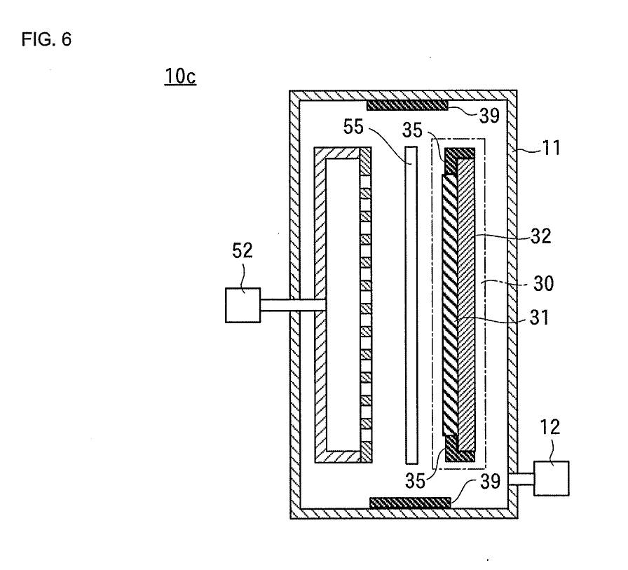

Moreover, the adhesion-preventing member of the present invention comprises Al₂O₃; and as long as the arithmetic average roughness of that adhering face on the surface of the adhesion-preventing member to which the film deposition particles are to be adhered is set at between at least 4 μm and at most 10 μm, in reference to FIG. 5 and FIG. 6, the present invention includes the adhesion-preventing members 35, 39 that are arranged at the positions where the film deposition particles of the film deposition apparatuses 10b, 10c; whereas, the film deposition apparatuses comprising a vacuum chamber 11, a vacuum evacuating device 12 evacuating the inside of the vacuum chamber 11, a gas introducing system 52 for introducing a gas into the vacuum chamber 11, and reacting means for forming film deposition particles by chemically reacting of the gas introduced into the vacuum chamber 11 constructed to deposit the film deposition material on the surface of the substrate 31, are adhered to.

In reference to FIG. 5, the reacting means is an electrode 53 for discharging the gas introduced into the vacuum chamber 11 when the film deposition apparatus 10b is a PE-CVD apparatus; and in reference to FIG. 6, when the film deposition apparatus 10c is a Cat-CVD apparatus, the reacting means is a filament 55 for decomposing the gas introduced into the vacuum chamber 11 through contacting the gas. Furthermore, reference numeral 54 in FIG. 5 is an electric power supply for applying a voltage to the electrode 53.

As for the adhesion-preventing member with respect to the present invention, a material of all Al₂O₃ is much more preferable to a material with Al₂O₃ coated on the surface of the metallic body. Because when using the material with Al₂O₃ coated on the surface of the metallic body, and when heated by the plasma, a metal having a higher thermal expansion rate than Al₂O₃, there is a risk of Al₂O₃ coating of the heat expanded metallic body to be peeled off.

### Examples

A first test adhesion-preventing member: Al₂O₃ in which the arithmetically average roughness of an adhering surface is set at less than 2 μm by blast process; a second test adhesion-preventing member: Al₂O₃ in which the arithmetically average roughness of an adhering surface is set at between at least 2 μm and less than 3 μm by blast process; a third test adhesion-preventing member: Al₂O₃ in which the arithmetically average roughness of an adhering surface was set at between at least 4 μm and less than 6 μm by blast process; and a fourth test adhesion-preventing member: Al₂O₃ in which the arithmetically average roughness of an adhering surface is set at between at least 6 μm and at most 10 μm by blast process were made.

Regarding the sputter deposition apparatus 10 of the present invention, in a testing step, one adhesion-preventing member from the first to fourth test adhesion-preventing members 25₁ to 25₄, and 35 is used as a mixed gas of Ar gas and O₂ gas introduced into the vacuum chamber 11, and by sputtering Si targets 21₁ to 21₄, SiO₂ particles are adhered to the surfaces of the adhesion-preventing members 25₁ to 25₄, and 35. When the targets 21₁ to 21₄ are continuously sputtered until the thickness of thin film (SiO₂ film) of an adhered material adhered to the adhering surfaces of the adhesion-preventing members 25₁ to 25₄, and 35 reach 1000 μm, the sputtering is stopped, the adhesion-preventing members 25₁ to 25₄, and 35 are carried to outside of the vacuum chamber 11, and adhered surfaces of the adhesion-preventing members 25₁ to 25₄, and 35 are photographed. The testing steps were repeated by using each of the first to fourth test adhesion-preventing members as the adhesion-preventing members 25₁ to 25₄, and 35.

Furthermore, it is previously known that when 10,000 of the substrates 31 are deposited with film from the sputter deposition apparatus 10 without exchanging the adhesion-preventing members 25₁ to 25₄, and 35, a SiO₂ film with the film thickness of 1000 μm is deposited on the adhering surfaces of the adhesion-preventing members 25₁ to 25₄, and 35.

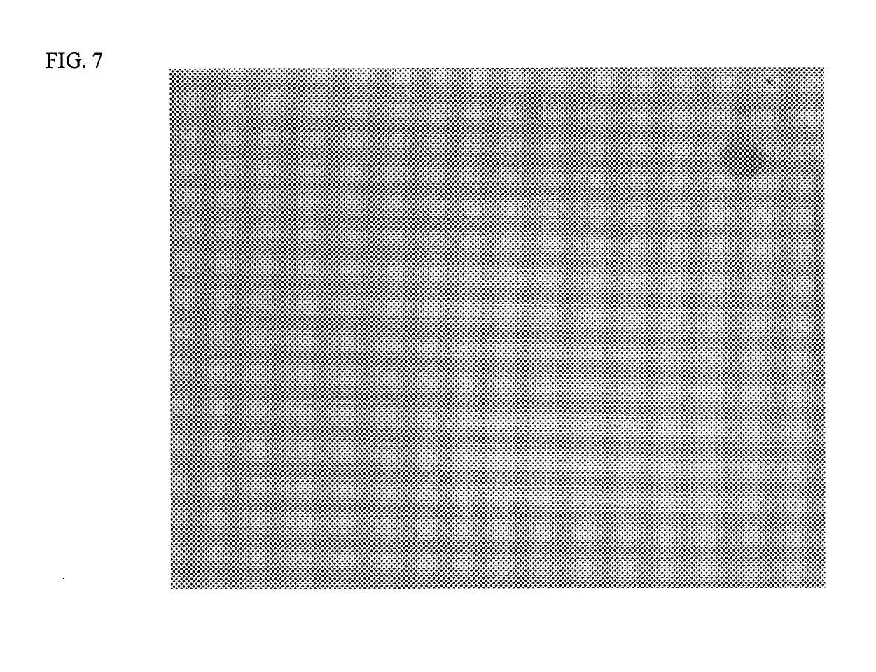

FIG. 7 is a photograph of the adhering surface of the first test adhesion-preventing member after the testing step. It is confirmed by the photograph that the film is peeled off by a wide area from the right side edge from the SiO₂ film adhering surface.

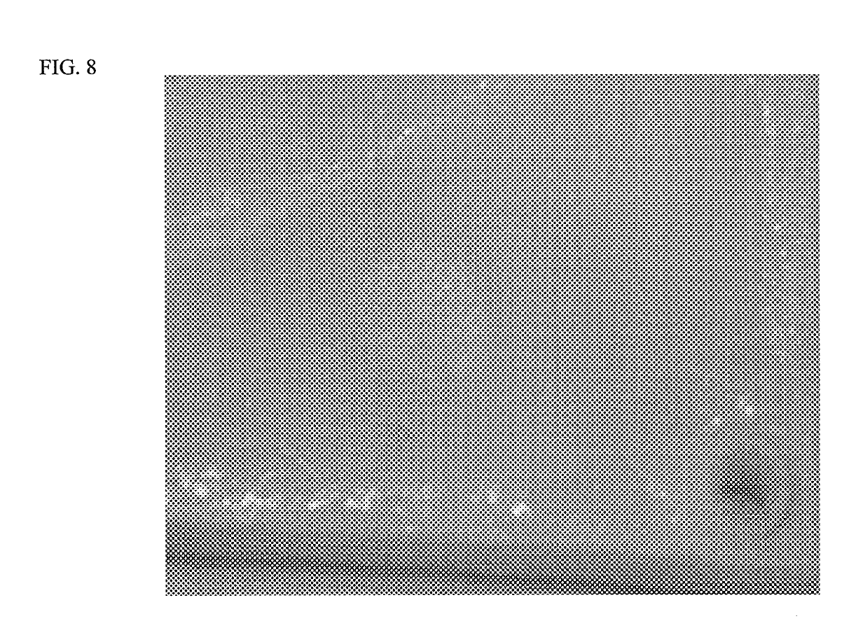

FIG. 8 is a photograph of the adhering surface of the second test adhesion-preventing member after the testing step. It is confirmed that the SiO₂ film is partially peeled off from the adhering surface.

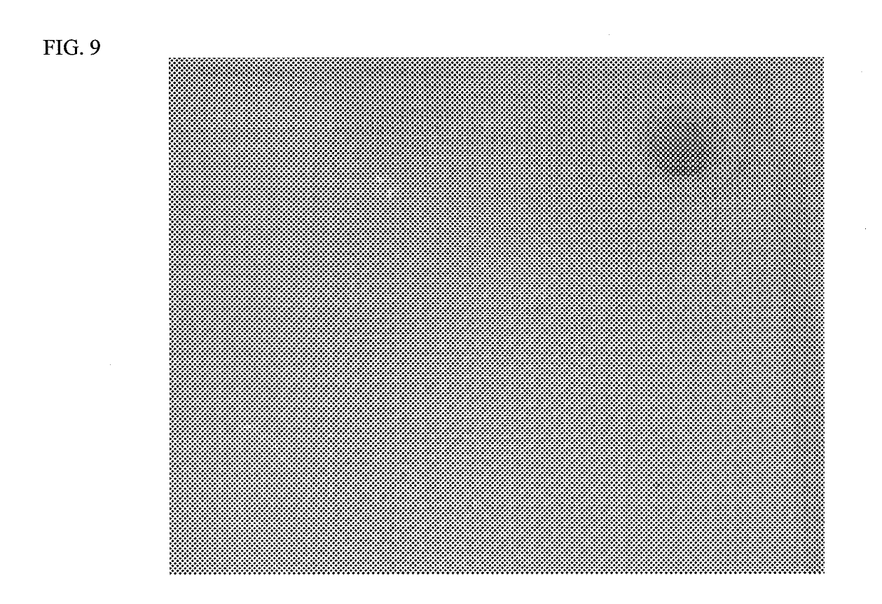

FIG. 9 is a photograph of the adhering surface of the third test adhesion-preventing member after the testing step. It confirmed that there are undulations on the surface of the SiO₂ film, but it is not confirmed that the film is peeled off from the adhering surface of the SiO₂ film.

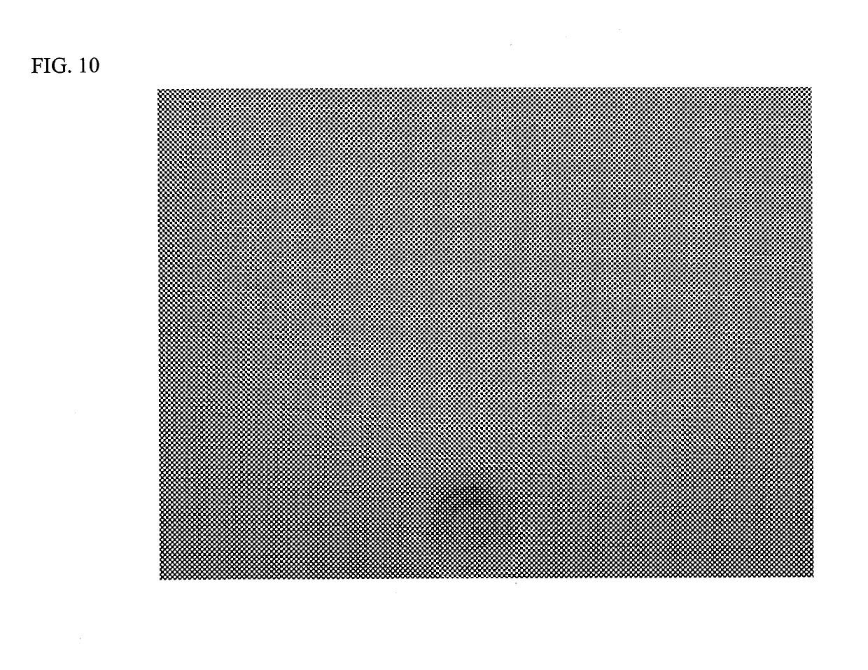

FIG. 10 is a photograph of the adhering surface of the fourth test adhesion-preventing member after the testing step. The photograph does not confirm the undulation on the surface of the SiO₂ film, and does not confirm that a film is peeled off from the SiO₂ film of the adhering surface.

According to the above results, it is understood that when using Al₂O₃ with the arithmetically average roughness of the adhering surface set at between at least 4 μm and at most 10 μm by the blast process, no adhering material is peeled off from the adhering surface of the adhesion-preventing member, although 10,000 substrates are processed.

Furthermore, when the arithmetically average roughness of the adhering surface is set at between at least 6 μm and at most 10 μm, it is understood that the effect preventing the peeling off of the adhering material is much larger.

### EXPLANATION OF THE REFERENCE NUMERALS

10 - - - sputter deposition apparatus (film deposition apparatus),
10a, 10b, 10c - - - film deposition apparatus,
11 - - - vacuum chamber,
12 - - - vacuum evacuating device,
13 - - - gas introducing system,
13b - - - reactive gas source (O₂ gas source),
21 - - - film deposition material,
21₁ to 21₄ - - - target (film deposition material),
25₁ to 25₄ - - - target-side adhesion-preventing member,
31 - - - substrate,
35 - - - substrate-side adhesion-preventing member,
37 - - - electric power supply,
39 - - - adhesion-preventing member arranged on an inner wall surface of a vacuum chamber,
52 - - - gas introduction system

What is claimed is:

1. A sputter deposition apparatus for forming a film on a film deposition surface of a substrate arranged at a position facing a sputtering surface of a target, said sputter deposition apparatus comprising:
a vacuum chamber;
a vacuum evacuation device evacuating the inside of the vacuum chamber;
a gas introduction system introducing a gas into the vacuum chamber;
a target having a sputtering surface exposed inside the vacuum chamber;
an electric power supply for applying a voltage to the target; and
an adhesion-preventing member arranged at a position in which sputtered particles sputtered from the sputtering surface of the target are to be attached,
wherein the adhesion-preventing member comprises Al₂O₃, and an arithmetically average roughness of that adhering face of a surface of the adhesion-preventing member to which the sputtered particles are attached is between at least 4 μm and at most 10 μm.

2. The sputter deposition apparatus according to claim 1, wherein the adhesion-preventing member comprises a target-side adhesion-preventing member arranged for the target such that the target-side adhesion-preventing member surrounds the sputtering surface of the target.

3. The sputter deposition apparatus according to claim 2, wherein
the target comprises a plurality of targets,
the targets are arranged in a line spaced apart from each other inside the vacuum chamber, the sputtering surfaces of the targets being arranged to be positioned on the same plane, and
the electric power supply applies an alternative voltage between two adjacent targets,
and wherein
a gap between an outer periphery of the sputtering surface of one of the two adjacent targets and an outer periphery of the sputtering surface of the other target is covered with the target-side adhesion-preventing member.

4. The sputter deposition apparatus according to claim 2, wherein
the target comprises a plurality of targets,
the targets are arranged in a line spaced apart from each other inside the vacuum chamber, sputtering surfaces of the targets being arranged to be positioned on the same plane, and
the electric power supply applies one of a DC voltage and an AC voltage between each of the targets and a substrate arranged at a position facing the sputtering surface of the target,
and wherein
a gap between an outer periphery of the sputtering surface of one of the two adjacent targets and the sputtering surface of the other target is covered with the target-side adhesion-preventing member.

5. The sputter deposition apparatus according to claim 1, wherein the adhesion-preventing member comprises a target-side adhesion-preventing member arranged for the substrate such that the target-side adhesion-preventing member surrounds a periphery of the film-forming surface of the substrate.

6. The sputter deposition apparatus according to one of claims 1 to 5, wherein the target comprises SiO₂.

7. The sputter deposition apparatus according to one of claims 1 to 5, wherein the target comprises Si, and the gas introduction system is O₂ gas source for discharging the O₂ gas.

8. An adhesion-preventing member which is arranged at that position in a film deposition apparatus to which film deposition particles are to be attached, the film deposition apparatus comprising:
a vacuum chamber;
a vacuum evacuating device evacuating the inside of the vacuum chamber; and
a unit for discharging film deposition particles from a film deposition materials arranged inside the vacuum chamber, wherein
the adhesion-preventing member comprises Al₂O₃, and an arithmetically average roughness of that adhering face of the surface of the adhesion-preventing member to which the sputtered particles are to be attached is set at between at least 4 μm and at most 10 μm.

9. An adhesion-preventing member which is arranged at that position in a film deposition apparatus to which film deposition particles are attached, the film deposition apparatus comprising:
a vacuum chamber;
a vacuum evacuating device evacuating the inside of the vacuum chamber;
a gas introduction system introducing a gas into the vacuum chamber; and
a reacting unit producing the film deposition particles from a chemical reaction of the gas introduced into the vacuum chamber, wherein
the adhesion-preventing member comprises Al₂O₃, and an arithmetically average roughness of that adhering surface on the surface of the adhesion-preventing member to which the sputtered particles are to be adhered is set at between at least 4 μm and at most 10 μm.
